(19) United States
(12) Patent Application Publication
(10) Pub. No.: US 2024/0206139 A1
(43) Pub. Date: Jun. 20, 2024

(54) ELECTROMAGNETIC WAVE SHIELDING SHEET

(71) Applicant: Shin-Etsu Chemical Co., Ltd., Tokyo (JP)

(72) Inventors: Ryo TANAKA, Annaka-shi (JP); Toshio SHIOBARA, Tokyo (JP)

(73) Assignee: Shin-Etsu Chemical Co., Ltd., Tokyo (JP)

(21) Appl. No.: 18/522,473

(22) Filed: Nov. 29, 2023

(30) Foreign Application Priority Data
Dec. 1, 2022 (JP) 2022-192664

(51) Int. Cl. H05K 9/00; D04H 1/4242; D04H 1/64

(52) U.S. Cl. CPC H05K 9/009; D04H 1/4242; D04H 1/641; D10B 2101/122; D10B 2401/063

(57) ABSTRACT

Provided is a high-strength electromagnetic wave shielding sheet exhibiting an excellent electromagnetic wave shielding performance irrespective of the oscillation directions of millimeter waves and terahertz waves. The electromagnetic wave shielding sheet may, for example, be a sheet containing a carbon nanotube unwoven cloth that has a thickness of not larger than 1 mm, a specific resistance of not larger than 0.005 $2·cm, and a longitudinal/lateral tensile strength ratio of 0.8 to 1.25; or a sheet with such carbon nanotube unwoven cloth being impregnated with a resin and/or with the resin being laminated on the carbon nanotube unwoven cloth.

### BACKGROUND OF THE INVENTION

### Field of the invention

The present invention relates to an electromagnetic wave shielding sheet.

### Background art

In recent years, high-speed communication such as 5G and 6G employing a high-frequency band (1 to 300 GHz) of an electromagnetic wave has become a hot topic. There are now more wireless devices utilizing electromagnetic waves for communication: ever-increasing electromagnetic waves contribute to malfunctions of electronic apparatuses when they are exposed to electromagnetic wave interferences therearound, or to information leaks due to the electromagnetic waves emitted from these apparatuses themselves. Further, in order to propel automated driving of automobiles or the like, which is seeing a rapid progress, transmission and reception of electromagnetic waves has to take place in a proper manner in various electromagnetic environments ranging from low-frequency electromagnetic waves to millimeter waves. In this regard, it has been a critical technical object to come up with measures for shielding electromagnetic waves: desired is an electromagnetic wave shielding material exhibiting a superior electromagnetic wave shielding performance with respect to microwaves, millimeter waves and terahertz waves. Further, due to the sophistication of electromagnetic wave usage, there is also a growing need(s) for new functionalities such as achieving a thin-filmed, light and/or large-area electromagnetic wave shielding material. There is a demand for an electromagnetic wave shielding sheet having a uniform electromagnetic wave shielding property as is the case with a metal without dependence on the oscillation directions of electromagnetic waves.

There have been proposed a number of electromagnetic wave shielding techniques using carbon black, graphene, carbon nanotube, conductive polymers, dielectric oxides and the like as electromagnetic wave shielding materials other than metal materials. Among them, carbon nanotubes made of carbon have attracted attention as a promising electromagnetic wave shielding material.

Carbon nanotubes are, for example, produced by a method where an aerogel is at first formed by reacting a gaseous reactive substance such as methane in the reaction region of a reactor, and an agglomerate obtained by agglomerating such aerogel is then turned into fibers or an unwoven cloth while being continuously moved outside of the reaction region (JP-A-2011-202338).

As an electromagnetic wave shielding material using carbon nanotubes, there are known, for example, a paste material with carbon nanotubes being dispersed in a resin (JP-A-2009-144000); and a water paint with carbon nanotubes being dispersed in a water solution (JP-A-2012-174833). However, neither of these materials can withstand a practical level as they are both difficult to handle and exhibit an insufficient electromagnetic wave shielding performance. Since the carbon nanotubes used are in fine fibrous shapes, they have a large specific surface area and can therefore not be dispersed in a resin by a large amount. In this way, the electromagnetic wave shielding material using such carbon nanotubes will also exhibit an insufficient electric conductivity.

Further, there is an electromagnetic wave shielding material using a carbon nanotube sheet formed by charge spinning (JP-A-2008-218859); the problems with this material are that it has a weak strength and is difficult to handle.

There is disclosed an electromagnetic wave shielding material that has had its conductivity improved by adding to a carbon nanotube sheet a protonation agent such as hydronium ions and hydrochloric acid, and by further adding thereto a ferromagnetic material such as iron and cobalt (Japanese Patent No.6182176); handling of the protonation agent has been a problem as it is a strongly acidic compound.

### SUMMARY OF THE INVENTION

Thus, it is an object of the present invention to provide a high-strength electromagnetic wave shielding sheet exhibiting an excellent electromagnetic wave shielding performance irrespective of the oscillation directions of millimeter waves and terahertz waves.

The inventors of the present invention found that in the case of an electromagnetic wave shielding sheet having a carbon nanotube unwoven cloth produced by a similar method as JP-A-2011-202338, since the carbon nanotubes are likely to be oriented in the drawing direction when forming the unwoven cloth, there is a difference in shielding effect between the drawing direction and a direction orthogonal thereto with regard to the oscillation direction of an electromagnetic wave. As a result of further diligently conducting a series of studies, the inventors of the present invention completed the invention by finding that an excellent electromagnetic wave shielding performance can be achieved with a carbon nanotube unwoven cloth that has a thickness of not larger than 1 mm, a specific resistance of not larger than 0.005 Ω·cm, and a longitudinal/lateral tensile strength ratio of 0.8 to 1.25, and also with a cured or uncured electromagnetic wave shielding sheet with such carbon nanotube unwoven cloth being impregnated with a resin and/or with such resin being laminated on such carbon nanotube unwoven cloth.

That is, the present invention is to provide the following electromagnetic wave shielding sheet.

[1]

An electromagnetic wave shielding sheet comprising a carbon nanotube unwoven cloth that has a thickness of not larger than 1 mm, a specific resistance of not larger than 0.005 Ω·cm, and a longitudinal/lateral tensile strength ratio of 0.8 to 1.25.

[2]

An electromagnetic wave shielding sheet with a carbon nanotube unwoven cloth that has a thickness of not larger than 1 mm, a specific resistance of not larger than 0.005 Ω·cm, and a longitudinal/lateral tensile strength ratio of 0.8 to 1.25 being impregnated with a resin; and/or with the resin being laminated on the carbon nanotube unwoven cloth.

[3]

The electromagnetic wave shielding sheet according to [2], wherein the resin with which the carbon nanotube unwoven cloth is impregnated and/or that is laminated on the carbon nanotube unwoven cloth is uncured.

[4]

The electromagnetic wave shielding sheet according to [2], wherein the resin with which the carbon nanotube unwoven cloth is impregnated and/or that is laminated on the carbon nanotube unwoven cloth is cured.

[5]

The electromagnetic wave shielding sheet according to any one of [2] to [4], wherein the resin with which the carbon nanotube unwoven cloth is impregnated and/or that is laminated on the carbon nanotube unwoven cloth is a heat-curable resin.

[6]

The electromagnetic wave shielding sheet according to any one of [2] to [4], wherein the resin with which the carbon nanotube unwoven cloth is impregnated and/or that is laminated on the carbon nanotube unwoven cloth is a thermoplastic resin.

[7]

The electromagnetic wave shielding sheet according to any one of [2] to [6], wherein the resin with which the carbon nanotube unwoven cloth is impregnated and/or that is laminated on the carbon nanotube unwoven cloth is in an amount of 10 to 1,000 parts by mass per 100 parts by mass of the carbon nanotube unwoven cloth. [8]

The electromagnetic wave shielding sheet according to [2], wherein the carbon nanotube unwoven cloth is a carbon nanotube unwoven cloth that has been treated with a coupling agent. [9]

The electromagnetic wave shielding sheet according to [5], wherein the heat-curable resin is at least one kind selected from the group consisting of an epoxy resin, an allylated epoxy resin, an allylated polyphenylene ether resin, a maleimide resin, a bismaleimide resin, a cyanate resin, a cyclopentadiene-styrene copolymer resin, a silicone resin, a phenolic resin, and an acrylic resin. [10]

The electromagnetic wave shielding sheet according to [6], wherein the thermoplastic resin is at least one kind selected from the group consisting of polyethylene, polypropylene, polyphenylene ether, polyetheretherketone, polyetherketone, polyethersulfone, and fluorine resin.

With the electromagnetic wave shielding sheet of the present invention, there can be achieved an excellent electromagnetic wave shielding performance irrespective of the directions of millimeter waves and terahertz waves. Thus, the electromagnetic wave shielding sheet of the present invention is suitable for use in high-speed and high-capacity communication-enabled devices, and transportation means such as vehicles and airplanes.

### BRIEF DESCRIPTION OF THE DRAWINGS

FIG. 1 is a schematic diagram showing a measurement system for measuring electromagnetic wave shielding property.

### DETAILED DESCRIPTION OF THE INVENTION

The present invention is described in detail hereunder. Carbon nanotube unwoven cloth

A carbon nanotube unwoven cloth used in the present invention has a thickness of not larger than 1 mm. Although there are no restrictions on the diameter and length of the carbon nanotubes, the carbon nanotube unwoven cloth used in this invention is normally one with single- to multi-walled carbon nanotube fibers having a diameter of not larger than 50 nm and a length of not larger than 2 mm being intertwined with one another.

Carbon nanotubes can be produced by reacting a carbon source such as methane and a catalyst such as ferrocene in a gas phase at a temperature of 1,000 to 1,500° C. As to continuous production, a production method disclosed in JP-A-2011-202338 is preferred.

An unwoven cloth can be produced by, for example, directly drawing and pressing carbon nanotubes. Further, an unwoven cloth can also be produced by at first preparing a sheet via a method such as filtration and papermaking where carbon nanotubes are to be suspended in water, an organic solvent or the like, and then drying the sheet.

A carbon nanotube unwoven cloth produced by direct drawing, a pressing treatment or the like is one with the fibers being oriented along the drawing direction and intertwined with one another. In contrast, an unwoven cloth produced by filtration and papermaking is one with the fibers being intertwined with one another without showing any orientation.

Since the carbon nanotube unwoven cloth used in the present invention has a uniform electromagnetic wave shielding property as is the case with a metal even against electromagnetic waves with different directions, the intertwinement of the fibers has to be uniform in any direction.

As for a method for examining whether or not the fibers in the unwoven cloth are uniformly intertwined with one another in a longitudinal direction and a lateral direction, the inventors of the present invention diligently conducted a series of studies and found that it can be easily evaluated by measuring the tensile strengths in the longitudinal and lateral directions.

Here, the longitudinal direction is defined as a direction exhibiting the highest tensile strength as a result of measuring the tensile strength of the carbon nanotube unwoven cloth from various directions: the lateral direction is defined as a direction that is perpendicular to the longitudinal direction. A metal-quality electromagnetic wave shielding property can be achieved irrespective of the directions of the electromagnetic waves, if the unwoven cloth is one exhibiting a favorable correlation between a longitudinal/lateral tensile strength ratio and a longitudinal/lateral transmission loss ratio, and in which the longitudinal/lateral tensile strength ratio is 0.8 to 1.25, preferably 1.0 to 1.25, more preferably 1.0 to 1.15.

Here, the longitudinal/lateral transmission loss ratio of the unwoven cloth is preferably 0.95 to 1.05, more preferably 0.97 to 1.03.

The unwoven cloth used in the present invention has a specific resistance of not larger than 0.005 Ω·cm, preferably not larger than 0.003 Ω·cm.

As carbon nanotubes, there may be used those that are commercially available. While no particular restrictions are imposed on the shape thereof, it is preferred that they are in the form of, for example, a powder, a slurry, or an unwoven cloth. Examples of commercially available products include EC1.0, EC1.5P, EC2.OP and MW-1 (by Meijo Nano Carbon Co.,Ltd); Miralon-T01 (by Nanocomp Technologies Inc.); CNTM10 and CNTM30 (by Tortech Nano Fibers); and ZEONANO SG101 (by Zeon Nano Technology Co., Ltd.).

### Inorganic Material

In the case of the carbon nanotube unwoven cloth of the present invention, by stuffing a highly electrically conductive inorganic material such as an inorganic powder, inorganic fibers and/or metal particles into the gaps of the intertwined carbon nanotube fibers, the electric conductivity of the unwoven cloth can be further improved, and the electromagnetic wave shielding performance thereof in a frequency band of 10 to 300 GHz can be improved as well.

Typical examples of an inorganic powder include carbon black, carbon nanotube, graphene, graphite, silica, zinc oxide, alumina, boron nitride, aluminum nitride, short carbon fibers, and short alumina fibers. Further, as metal particles, there may be added copper, iron, silver or gold particles: or resin particles surface-coated with these metals.

The metal particles and/or inorganic powder may be laminated on and/or impregnate the carbon nanotube unwoven cloth by being dispersed in a resin.

Moreover, in order to further improve the thermal conductivity of the electromagnetic wave shielding sheet, there may also be used inorganic particles and fibers, such as silica particles, zinc oxide particles, alumina particles, boron nitride particles, aluminum nitride particles, short carbon fibers, short alumina fibers, quartz fibers, and glass fibers. By using these materials, the thermal conductivity of the electromagnetic wave shielding sheet can be 50 to 80 W/mK.

There are no particular limitations on the shapes of these inorganic materials: a shape close to a spherical shape is preferred as filling will be easier, and a preferred average particle size thereof is 0.5 to 30 μm in terms of heat dissipation and electric conductivity.

The inorganic material may be dispersed into the unwoven cloth by any method. For example, there may be employed a method where the inorganic material is to be stuffed into the unwoven cloth by a pressing device or a laminator; a method where the inorganic material is to be dispersed in any solvent, followed by spraying the dispersion onto the unwoven cloth with a sprayer and then removing the solvent by drying: or even a combination of these methods.

Any solvent may be used as the solvent of the dispersion: a solvent with a high volatility is preferred, examples of which include water, an alcohol such as ethanol and IPA, acetone, toluene, a hydrocarbon-based solvent, and a silicone-based solvent.

It is preferred that the concentration of the dispersion be 0.1 to 100 parts by mass per 100 parts by mass of the inorganic material.

A dispersed amount of the inorganic material to the unwoven cloth is preferably 0.01 to 100 parts by mass per 100 parts by mass of the carbon nanotube unwoven cloth. Resin to impregnate and/or be laminated on carbon nanotube unwoven cloth

The carbon nanotube unwoven cloth of the invention has a favorable electric conductivity, and also exhibits an excellent electromagnetic wave shielding performance in a wide range of frequency of 10 GHz or higher. However, since the strength of a carbon nanotube unwoven cloth itself is insufficient on its own, it is easily tearable and has no adhesiveness to a base material: such unwoven cloth is hard to use as it is.

The present invention is to solve these problems, and relates to a B-staged electromagnetic wave shielding sheet prepared by impregnating a carbon nanotube unwoven cloth with a resin and/or laminating the resin on the carbon nanotube unwoven cloth, and then semi-curing the same; and to a cured electromagnetic wave shielding sheet having a certain strength. As the resin that is used to impregnate and/or is to be laminated on the carbon nanotube unwoven cloth, the following heat-curable resin and/or thermoplastic resin are preferred. Heat-curable resin

Examples of the heat-curable resin used in the present invention include an epoxy resin, an allylated epoxy resin, an allylated polyphenylene ether resin, a maleimide resin, a bismaleimide resin, a cyanate resin, a cyclopentadiene-styrene copolymer resin, a silicone resin, a phenolic resin, and an acrylic resin. Particularly, preferred are bismaleimide resins represented by the following general formulae (1) and (2) as they are superior in heat resistance, low elasticity, high toughness and adhesiveness.

### Bismaleimide Resin Represented by General Formula (1)

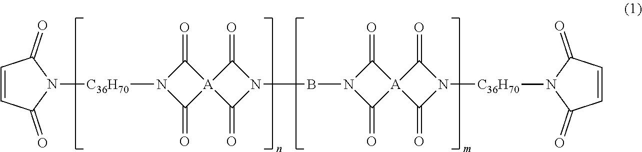

In the formula (1), A independently represents a tetravalent organic group having an aromatic ring or aliphatic ring. B is an alkylene chain having 6 to 18 carbon atoms and a divalent aliphatic ring that may contain a hetero atom. n is a number of 1 to 10. m is a number of 0 to 10. —C₃₆H₇₀— represents a dimer acid frame-derived hydrocarbon group. Bismaleimide resin represented by general formula (2)

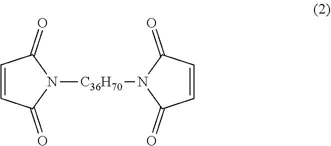

In the formula (2), —C₃₆H₇₀— represents a dimer acid frame-derived hydrocarbon group.

A dimer acid here refers to a liquid dibasic acid whose main component is a dicarboxylic acid having 36 carbon atoms, which is produced by dimerizing an unsaturated fatty acid having 18 carbon atoms and employing a natural substance such as a vegetable fat or oil as its raw material; a dimer acid frame may contain multiple structures as opposed to one single type of frame, and there exist several types of isomers. Typical dimer acids are categorized under the names of (a) linear type, (b) monocyclic type, (c) aromatic ring type, and (d) polycyclic type.

In this specification, a dimer acid frame refers to a group induced from a dimer diamine having a structure established by substituting the carboxy groups in such dimer acid with primary aminomethyl groups. That is, as a dimer acid frame, it is preferred that the bismaleimide resin represented by the general formula (1) or (2) have a group obtained by substituting the two carboxy groups in any of the following dimer acids (a) to (d) with methylene groups.

Further, as for the dimer acid frame-derived hydrocarbon group in a maleimide compound, more preferred from the perspectives of heat resistance and reliability of a cured product are those having a structure with a reduced number of carbon-carbon double bonds in the dimer acid frame-derived hydrocarbon group due to a hydrogenation reaction.

Here, in general, a dimer acid may contain a trimer (trimer acid) due to the fact that its raw material is a natural substance such as a vegetable fat or oil; it is preferred that the dimer acid-derived hydrocarbon groups be present at a high ratio of, for example, 95% by mass or higher among the dimer acid- and trimer acid-derived hydrocarbon groups, as there tend to be observed excellent dielectric properties, an excellent moldability as viscosity will easily decrease when heated, and a less impact of moisture absorption.

In this specification, a dimer acid (trimer acid) frame refers to a group induced from a dimer diamine (trimer triamine) having a structure established by substituting the carboxy groups in such dimer acid (trimer acid) with primary aminomethyl groups.

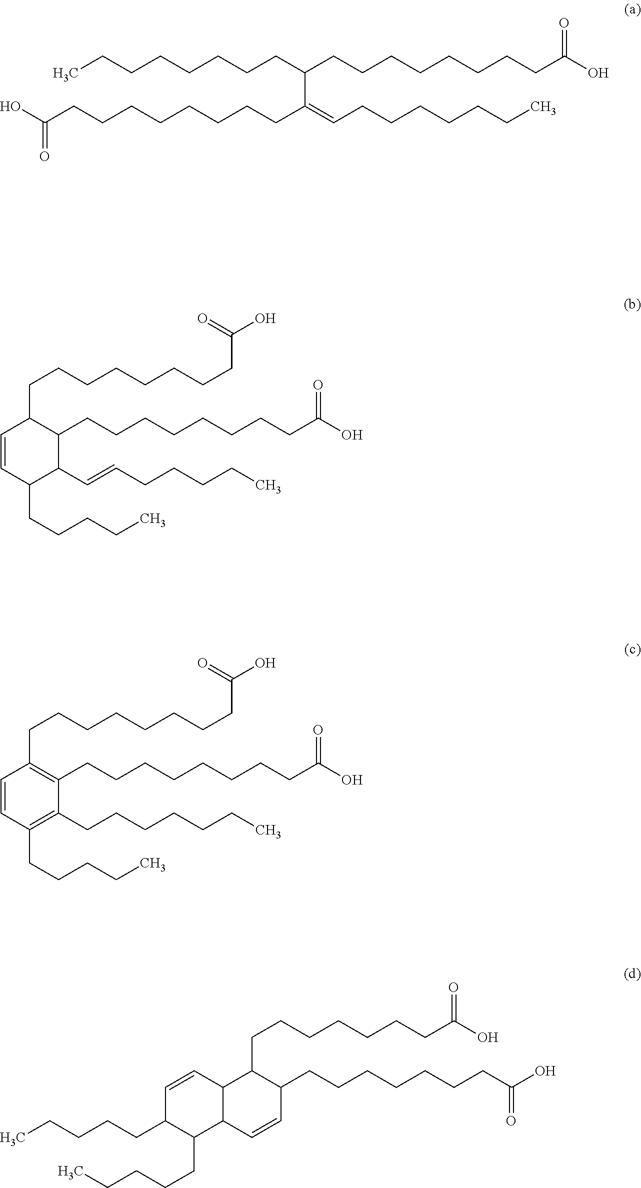 [SMILES: CCCCCCC/C=C(/CCCCCCCCC(=O)O)C(CCCCCCCC)CCCCCCCCC(=O)O ; CCCCC/C=C/C1C(CCCCC)C=CC(CCCCCCCCC(=O)O)C1CCCCCCCCC(=O)O ; CCCCCCCc1c(CCCCC)ccc(CCCCCCCCC(=O)O)c1CCCCCCCCC(=O)O ; CCCCCC1C=CC2C(C=CC(CCCCCCCC(=O)O)C2CCCCCCCC(=O)O)C1CCCCC]

In the formula (1). A represents a tetravalent organic group having an aromatic ring or aliphatic ring. and it is particularly preferred that A be any one of the tetravalent organic groups expressed by the following structural formulae.

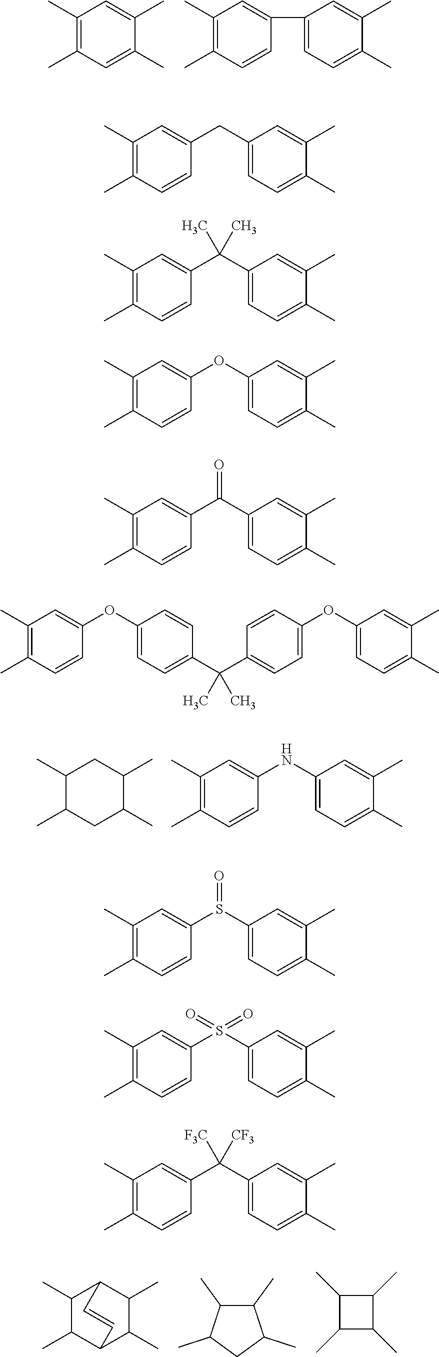

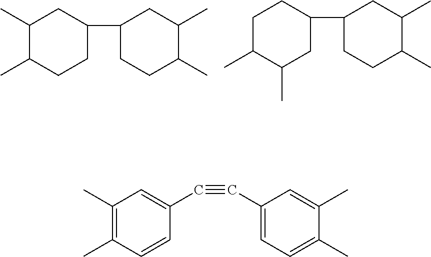

Bonds in the above structural formulae that are yet unbonded to substituent groups are to be bonded to carbonyl carbons forming cyclic imide structures in the formula (1).

In the formula (1), B is an alkylene chain having 6 to 18 carbon atoms and a divalent aliphatic ring that may contain a hetero atom, and it is particularly preferred that B be any one of the groups expressed by the following structural formulae.

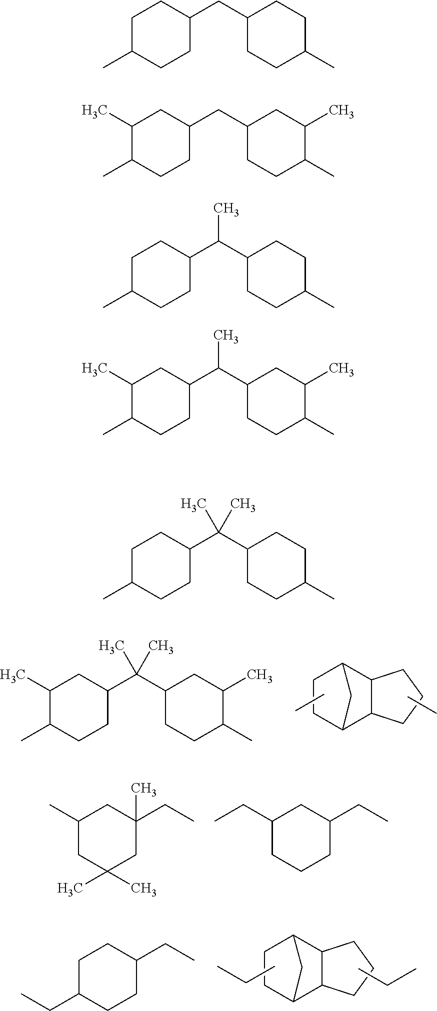

Bonds in the above structural formulae that are yet unbonded to substituent groups are to be bonded to nitrogen atoms forming cyclic imide structures in the formula (1).

A typical bismaleimide resin may for example be the SLK-2000 series, SLK-6895 or SLK-3000 (all by Shin-Etsu Chemical Co., Ltd.). Further, a heat-curable cyclopentadiene-styrene copolymer resin may also be used as a high heat resistance resin.

As for each heat-curable resin, there may be used one kind thereof, or two or more kinds thereof in combination. Further, the above heat-curable resin and/or a later-described thermoplastic resin may be mixed with the bismaleimide resins represented by the general formulae (1) and (2) upon use.

### Reaction Initiator

A reaction initiator may be added to the bismaleimide resin to initiate and promote a cross-linking reaction of the maleimide compound, and a reaction between the maleimide groups and reactive groups capable of reacting with them.

There are no particular restrictions on such reaction initiator so long as it is capable of promoting a cross-linking reaction, examples of which may include ion catalysts such as imidazoles, an organic phosphorus compound, tertiary amines, quaternary ammonium salts, a boron trifluoride-amine complex, organophosphines, and an organophosphonium salt: organic peroxides such as diallyl peroxide, dialkyl peroxide, peroxide carbonate, and hydroperoxide: and radical polymerization initiators such as azoisobutyronitrile.

Among them, preferred are an organic peroxide and a radical polymerization initiator if the reaction initiator is to promote a reaction of the bismaleimide resin alone, or if the reactive groups in a later-described heat-curable resin which is not the bismaleimide resin and contains reactive groups capable of reacting with maleimide groups are carbon-carbon double bond-containing groups such as a maleimide group, an alkenyl group and a (meth)acryloyl group. Examples of the organic peroxide include dicumyl peroxide, t-butyl peroxybenzoate, t-amyl peroxy benzoate, dibenzoyl peroxide, dilauroyl peroxide, 2,5-dimethyl-2,5-di(t-butylperoxy)hexane, 1,1-di(t-butylperoxy)cyclohexane, di-t-butyl peroxide, and dibenzoyl peroxide.

Further, an organic phosphorus compound and basic compounds such as imidazoles and tertiary amines are preferred if the reactive groups in the heat-curable resin which is not the bismaleimide resin and contains reactive groups capable of reacting with maleimide groups are an epoxy group, a hydroxyl group or an acid anhydride group. While it is also possible to use imidazole or amines for homopolymerization of maleimide groups, the usage of imidazole and an organic phosphorus compound requires an extremely high temperature, and the usage of amines may result in an extremely short pot life.

It is preferred that the reaction initiator be added in an amount of 0.05 to 10 parts by mass, more preferably 0.1 to 5 parts by mass, per 100 parts by mass of the bismaleimide resin. Further, if adding another heat-curable resin to the composition, it is preferred that the reaction initiator be added in an amount of 0.05 to 10 parts by mass, particularly preferably 0.1 to 5 parts by mass, per a total of 100 parts by mass of the bismaleimide resin and such another heat-curable resin component. It is not preferable if the amount of the reaction initiator is out of the above ranges, because curing may take place in an extremely slow or fast manner when molding the bismaleimide resin composition. Further, the cured product obtained may also exhibit a poor balance between the heat resistance and moisture resistance thereof.

One kind of such reaction initiator may be used alone, or two or more kinds thereof may be used in combination.

### Thermoplastic Resin

Typical examples of a thermoplastic resin include polyethylene, polypropylene, polyphenylene ether, polyetheretherketone, polyetherketone, polyethersulfone, and fluorine resin. Particularly, preferred is a thermoplastic resin that is soluble in a solvent. As for the thermoplastic resin, one kind thereof may be used alone, or two or more kinds thereof may be used in combination.

The number average molecular weight (Mn) of the resin is preferably 500 to 100,000, more preferably 800 to 50,000, even more preferably 1,000 to 10,000.

The number average molecular weight (Mn) mentioned in this specification refers to a number average molecular weight measured by GPC under the following conditions, using polystyrene as a reference substance.

[GPC measurement conditions]

Developing solvent: Tetrahydrofuran (THF)

Flow rate: 0.35 mL/min

Detector: Differential refractive index detector (RI)

Column: TSK Guardcolumn Super H-L
TSK gel Super HZ4000 (4.6 mm I.D.×15 cm×1)
TSK gel Super HZ3000 (4.6 mm I.D.×15 cm×1)
TSK gel Super HZ2000 (4.6 mm I.D.×15 cm×2)
(All manufactured by Tosoh Corporation)

Column temperature: 40° C.
Sample injection volume: 5 μL (THF solution with a concentration of 0.2% by mass)

An impregnation amount and/or lamination amount of the resin to the unwoven cloth is preferably 10 to 1,000 parts by mass per 100 parts by mass of the carbon nanotube unwoven cloth.

### Method for Producing Electromagnetic Wave Shielding Sheet

There may be employed any method for producing a carbon nanotube unwoven cloth from a dispersion of single-walled and/or multi-walled carbon nanotubes; examples of such method may include a method where the dispersion is subjected to pressurization or filtration under a reduced pressure before drying, a method where a bar coater or the like is used to apply the dispersion to a base material before drying, and a freeze-drying method where only the solvent is to be sublimated from a frozen dispersion.

The electromagnetic wave shielding sheet of the present invention can be produced by any method. There may be listed, for example, a wet method where a resin is to be dissolved in a solvent (volatile) to have its viscosity reduced, followed by impregnating the carbon nanotube unwoven cloth with such resin or laminating such resin on the carbon nanotube unwoven cloth; a melt rolling method where the resin is to be heated to have its viscosity reduced, followed by impregnating the carbon nanotube unwoven cloth with such resin or laminating such resin on the carbon nanotube unwoven cloth; and a transfer method where a resin varnish is to be turned into a film with a coater or the like, followed by using a pressing device or a laminator to transfer the film onto the carbon nanotube unwoven cloth and impregnate the unwoven cloth with such film. Here, an impregnated carbon nanotube unwoven cloth is at first produced by any of the methods, followed by, if necessary, pressure-laminating a film of a resin thereon, and then semi-curing (i.e. B-staging) or curing the same to obtain an electromagnetic wave shielding sheet.

In the wet method, a resin-impregnated electromagnetic wave shielding sheet is produced by at first impregnating the unwoven cloth with the resin and then removing the solvent. Solvent remaining in the electromagnetic wave shielding sheet will cause a problem of, for example, worsening an operation efficiency by leaving negative impacts at the time of molding. Thus, an amount of the solvent remaining in the electromagnetic wave shielding sheet is not larger than 1% by mass, desirably not larger than 0.5% by mass.

Although depending on the boiling point of the solvent used, the method for removing the solvent is preferably a heat treatment performed at 80 to 150° C. for about 10 min to an hour: this heat treatment allows the solvent to be removed easily.

The melt rolling method is advantageous from various perspectives such as the fact that a relatively favorable operation efficiency can be achieved as a solvent removal step is not particularly necessary. In the melt rolling method, the carbon nanotube unwoven cloth is to be widened to a required width with a bar or the like, and is then vertically sandwiched by the resin (heat-curable resin and/or thermoplastic resin) that has been turned into a film, using a release paper, followed by nipping the same with several pairs of heating metal rollers that are installed at a substantially same height with respect to an advancing direction of the carbon nanotube unwoven cloth, thereby allowing the carbon nanotube unwoven cloth to be impregnated with the heat-curable resin and/or thermoplastic resin, and/or allowing such heat-curable resin and/or thermoplastic resin to be laminated on the carbon nanotube unwoven cloth, thus obtaining the electromagnetic wave shielding sheet. In the melt rolling method, since the nip pressure is a linear pressure, the number of the nip rollers is preferably increased to achieve a satisfactory impregnating ability. Further, pressure molding may be performed via molding press such as multistage press where heating is possible without a heating metal roller(s).

The transfer method is such a method where a base material film is to be coated with the resin varnish to then obtain a resin film by drying the solvent, followed by sandwiching both surfaces of the carbon nanotube unwoven cloth with such resin film, and then press-bonding the same by a laminator or a pressing device, thereby allowing the resin film to be transferred onto the carbon nanotube unwoven cloth and the carbon nanotube unwoven cloth to be impregnated with such resin film, and/or allowing the resin film to be laminated on the carbon nanotube unwoven cloth.

Any film may be used as the base material film: preferred are, for example, a PET film, PE film, PP film, Teflon film and Aflex film from which the resin film can be easily peeled off.

If necessary, the surface of the base material film may be subjected to various surface treatments such as corona treatment, plasma treatment or silicone treatment.

Any solvent may be used as the solvent of the resin varnish: a solvent with a high volatility is preferred, examples of which include an alcohol such as ethanol and IPA, acetone, toluene, xylene, anisole, a hydrocarbon-based solvent, and a silicone-based solvent.

The concentration of the resin varnish is preferably 0.1 to 200 parts by mass per 100 parts by mass of the resin.

Any method may be used to coat the base material film with the resin varnish; it is preferred to use a spin coater or a bar coater for the sake of easiness.

A temperature for drying the resin film on the base material film is preferably one at which the heat-curable resin will not react, preferably 30 to 120° C.

In addition, if necessary, pressurizing and heating may be conducted when sandwiching both surfaces of the carbon nanotube unwoven cloth with the resin film, press-bonding the same by a laminator or a pressing device, and transferring the resin film onto the carbon nanotube unwoven cloth.

As the electromagnetic wave shielding sheet of the carbon nanotube unwoven cloth using the heat-curable resin, there are an electromagnetic wave shielding sheet in which the resin has completely cured: and an electromagnetic wave shielding sheet in a semi-cured state.

As for the cured electromagnetic wave shielding sheet, there may actually be produced a hard and tough electromagnetic wave shielding sheet to an electromagnetic wave shielding sheet that is flexible and capable of conforming with various shapes, by selecting the chemical structure, impregnation amount, lamination amount and curing method of the heat-curable resin.

As for the semi-cured electromagnetic wave shielding sheet, it can be bonded to a housing and a container storing a communication device or the like by being matched to the shape(s) of these housing and container and then press-bonded thereto under a pressure and heat.

Since the electromagnetic wave shielding sheet of the present invention can be freely produced as that having a small-area sheet size to that having a large-area sheet size, there is no limitation to an area for shielding electromagnetic waves.

Even when employing the thermoplastic resin, the electromagnetic wave shielding sheet can likewise be produced as is the case where the heat-curable resin is used.

In the present invention, when impregnating the carbon nanotube unwoven cloth with the resin, by surface-treating the carbon nanotube unwoven cloth with a coupling agent, the carbon nanotube unwoven cloth and the resin shall tightly adhere to each other, which allows the durability of the electromagnetic wave shielding sheet to be improved.

As the coupling agent, there may be used a silane coupling agent and an alkoxide-based compound such as titanium alkoxide and aluminum alkoxide. Particularly, a silane coupling agent is preferred: one preferable example thereof may be a compound represented by a general formula Y—Si—X₃. Here, Y is an organic group having a functional group such as an amino group, an epoxy group, a hydroxyl group, a carboxyl group, a vinyl group, a methacrylic group and a mercapto group: X is a hydrolyzable functional group such as an alkoxy group.

Specific and typical examples of the compound represented by the general formula Y—Si—X₃ include γ-glycidoxypropyltrimethoxysilane, vinyltriethoxysilane, γ-aminopropyltriethoxysilane, γ-mercaptopropyltrimethoxysilane, γ-methacryloxypropyltrimethoxysilane, γ-aminobenzyltriethoxysilane, and γ-aminophenyltriethoxysilane.

An appropriate amount of such coupling agent used is in a range of 0.5 to 20 parts by mass per 100 parts by mass of the bismaleimide resin.

The electromagnetic wave shielding sheet of the present invention has an electromagnetic wave shielding property of not lower than 50 dB, preferably not lower than 60 dB, in the frequency band of 10 to 300 GHz.

This electromagnetic wave shielding sheet may also be a laminated body with a thermoplastic film such as a polyester film being laminated on the upper and lower surfaces of the electromagnetic wave shielding sheet as a protective film.

### WORKING EXAMPLES

The present invention is described in greater detail hereunder with reference to working examples: the invention shall not be limited to these working examples. In the present invention, “part(s)” refers to “part(s) by mass”. The materials used in the working as well as comparative examples are as follows. Further, the physical property and characteristic values in the present invention were measured by the following methods.

### Working Example 1

Single-walled carbon nanotubes (EC-1.5P by Meijo Nano Carbon Co.,Ltd) and pure water were subjected to high-speed stirring for 1 min using a mixer (IFM-800D by Iwatani Corporation), thereby obtaining 1 L of an aqueous solution having a single-walled carbon nanotube concentration of 0.5 g/L. This aqueous solution was then filtrated with a reduced-pressure filtration device in which a Φ185 mm filter paper was placed, thereby obtaining a sheet.

The sheet obtained was dried at 70° C. for 10 hours, and then at 110° C. for another 10 hours. After being peeled from the filter paper, the sheet was then cut into 12 cm-squared pieces to obtain unwoven cloths having a thickness of 52 um.

The specific resistance of this unwoven cloth was 1.82E-04 (Ω·cm).

An electromagnetic wave shield measurement device manufactured by KEYCOM Corporation was used to measure a transmission loss at 70 GHz with regard to this unwoven cloth.

Further, the tensile strengths in the longitudinal and lateral directions were measured by measuring the tensile strengths of test pieces cut out of the unwoven cloth. The tensile strength of the test piece cut out was measured from various directions, where the longitudinal direction was defined as a direction exhibiting the highest tensile strength; and the lateral direction was defined as a direction that was perpendicular to the longitudinal direction.

The results of transmission loss and tensile strength are both shown in Table 1.

### Working Example 2

An unwoven cloth was produced and the tensile strengths and transmission loss thereof were measured in a similar manner as the working example 1, except that EC2.0P (by Meijo Nano Carbon Co.,Ltd) was used instead of EC-1.5P (by Meijo Nano Carbon Co.,Ltd). The results are shown in Table 1.

### Comparative Example 1

As a result of measuring the specific resistance of a multi-walled carbon nanotube unwoven cloth having a thickness of 78 μm (CNTM30 by Tortech Nano Fibers), the specific resistance was conformed to be 1.51E-03 (Ω·cm).

The tensile strengths and transmission loss of this unwoven cloth were measured in a similar manner as the working example 1. The results are shown in Table 3.

### Comparative Example 2

As a result of measuring the specific resistance of a multi-walled carbon nanotube unwoven cloth having a thickness of 32 μm (CNTM10 by Tortech Nano Fibers), the specific resistance was conformed to be 2.22E-03 (Ω·cm).

The tensile strengths and transmission loss of this unwoven cloth were measured in a similar manner as the working example 1. The results are shown in Table 3.

### Working Example 3

An unwoven cloth having a thickness of 52 μm was produced and the tensile strengths and transmission loss thereof were measured in a similar manner as the working example 1, except that the sheet was produced from 1 L of an aqueous solution having a carbon nanotube concentration of 0.5 g/L, which was prepared by crushing the unwoven cloth of the comparative example 1 and then dispersing the crushed pieces in water. The results are shown in Table 1.

### Working Example 4

An unwoven cloth having a thickness of 75 μm was produced and the tensile strengths and transmission loss thereof were measured in a similar manner as the working example 1, except that the concentration of the aqueous solution was set to be 1 g/L. The results are shown in Table 1.

### Working Example 5

There was prepared a toluene solution comprised of 100 parts by mass of a bismaleimide resin (A-1) (SLK-3000 by Shin-Etsu Chemical Co., Ltd., number average molecular weight 5,200), 1 part by mass of a curing catalyst (dicumylperoxide, “PERCUMYL D” by NOF CORPORATION), and 200 parts by mass of toluene.

By impregnating the carbon nanotube unwoven cloth prepared in the working example 1 with this toluene solution and then removing toluene by drying, there was produced an unwoven cloth impregnated with a semi-cured bismaleimide resin, that had 250 parts by mass of resin per 100 parts by mass of the carbon nanotube unwoven cloth.

This unwoven cloth was then pressurized and cured at 150° C. for 30 min using a pressing device, thereby obtaining an electromagnetic wave shielding sheet having 200 parts by mass of resin per 100 parts by mass of the carbon nanotube unwoven cloth. The sheet had a thickness of 80 μm.

Using this sheet, tensile strengths and transmission loss were measured in a similar manner as the working example 1. The results are shown in Table 2.

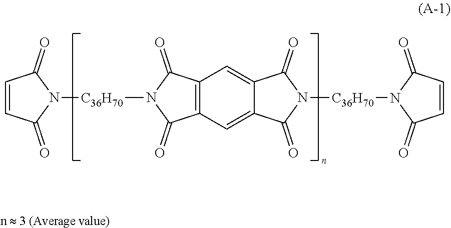

—C₃₆H₇₀— represents a dimer acid frame-derived hydrocarbon group.

### Working Example 6

There was prepared a 15 μm-thick maleimide resin film containing 100 parts by mass of the bismaleimide resin (A-1) and I part by mass of the curing catalyst (dicumylperoxide, “PERCUMYL D” by NOF CORPORATION).

At a temperature of 80° C., it took 1 min to laminate this maleimide resin film on both surfaces of the unwoven cloth produced in the working example 3, followed by pressing them at 150° C. for 15 min to impregnate the unwoven cloth with the maleimide resin film, thereby obtaining a semi-cured solid sheet.

Next, an electromagnetic wave shielding sheet was produced by performing heating at 150° C. for two hours. The sheet had a thickness of 80 μm.

Using this sheet, tensile strengths and transmission loss were measured in a similar manner as the working example 1. The results are shown in Table 2.

### Working Example 7

A 20 μm-thick silicone resin film was produced in a similar manner as the working example 6, using a silicone resin (A-2) (PLF-100D by Shin-Etsu Chemical Co., Ltd., number average molecular weight 5,000, 50% toluene solution of curable silicone resin) instead of the bismaleimide resin (A-1) of the working example 6.

At a temperature of 80° C., it took 1 min to laminate this silicone resin film on both surfaces of the single-walled carbon nanotube unwoven cloth produced in the working example 1, followed by pressing them at 150° C. for 15 min to impregnate the unwoven cloth with the silicone resin film, thereby obtaining a semi-cured solid sheet.

Next, an electromagnetic wave shielding sheet was produced by performing heating at 150° C. for two hours. The sheet had a thickness of 100 um.

Using this sheet, tensile strengths and transmission loss were measured in a similar manner as the working example 1. The results are shown in Table 2.

### Working Example 8

A fluorine resin film was obtained by molding a thermoplastic fluorine resin (A-3) (Dyneon THV 500GZ by 3M Japan Limited) into a 30 μm-thick resin film at 200° C., using a pressing device.

Both surfaces of the single-walled carbon nanotube unwoven cloth produced in the working example I were then sandwiched by this fluorine resin film, followed by press-bonding them at 200° C. for 30 min using a pressing device, thereby obtaining an electromagnetic wave shielding sheet. The sheet had a thickness of 110 μm.

Using this sheet, tensile strengths and transmission loss were measured in a similar manner as the working example 1. The results are shown in Table 2.

### Comparative Example 3

There was prepared a 30 μm-thick maleimide resin film containing 100 parts by mass of the bismaleimide resin (A-1) (SLK-3000 by Shin-Etsu Chemical Co., Ltd.) and 1 part by mass of the curing catalyst (dicumylperoxide, “PERCUMYL D” by NOF CORPORATION).

At a temperature of 80° C., it took 1 min to laminate this maleimide resin film on both surfaces of the unwoven cloth of the comparative example 1, followed by pressing them at 150° C. for 15 min to impregnate the unwoven cloth with the maleimide resin film, thereby obtaining a semi-cured solid sheet.

Next, an electromagnetic wave shielding sheet was produced by performing heating at 150° C. for two hours. The sheet had a thickness of 90 μm.

Using this sheet, tensile strengths and transmission loss were measured in a similar manner as the working example 1. The results are shown in Table 3.

### Measurement Methods

### (1) Specific Resistance

The specific resistance of each carbon nanotube unwoven cloth (electromagnetic wave shielding sheet) was calculated by measuring the surface resistivity and thickness thereof, and then putting these values into the following formula.

Specific resistance (Ω·cm)=Surface resistivity (Ω/□)×thickness (cm)

The surface resistivity of each carbon nanotube unwoven cloth (electromagnetic wave shielding sheet) was measured by Loresta-GX MCP-T700 (low resistance, resistivity meter by Nittoseiko Analytech Co., Ltd.). The surface resistivity of each carbon nanotube unwoven cloth (electromagnetic wave shielding sheet) impregnated with the resin and/or with the resin being laminated thereon was measured by an eddy-current method sheet resistance/resistivity measurement instrument (EC-80P by NAPSON CORPORATION). The measured value was then used to calculate specific resistance.

The thickness of each carbon nanotube unwoven cloth (electromagnetic wave shielding sheet) was measured by a micrometer (by Mitutoyo Corporation).

The results are shown in Tables 1 to 3.

### (2) Electromagnetic Wave Shielding Property

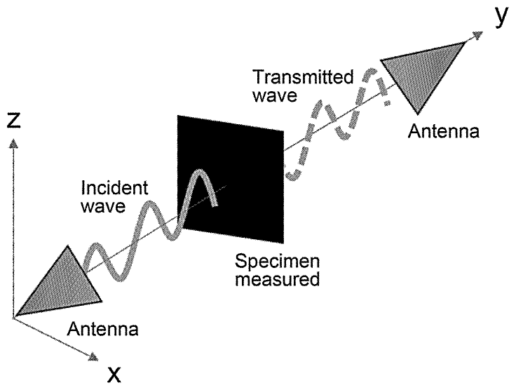

Using the unwoven cloth cut out into a 12 cm-squared piece, electromagnetic wave shielding property was evaluated by measuring the transmission losses in the two orthogonal longitudinal and lateral directions at 70 GHz with the aid of an electromagnetic wave shield measurement device (by KEYCOM Corporation). FIG. 1 is a schematic diagram showing the measurement system. The unwoven cloth as a specimen was placed between two antennas on the y-axis that were connected to a vector network analyzer (by ANRITSU CORPORATION) in such a manner that the surface of the unwoven cloth was positioned orthogonal to the y-axis. The specimen was irradiated by an electromagnetic wave with electric field oscillation in the z-axis direction, where the electromagnetic wave that had transmitted through the specimen was measured, and transmission attenuation (dB) was recorded. Further, by tilting the specimen by 90° about the y-axis, the transmission attenuations (dB) in the two longitudinal and lateral directions were able to be measured. The results are shown in Tables 1 to 3.

### (3) Tensile Strength

Test pieces were cut out from the unwoven cloth produced as above, and Autograph (AGS-500NS by SHIMADZU CORPORATION) was used to measure the tensile strength of the test piece from various directions under conditions of: jig gripping width 50 mm; tensile speed 100 mm/min. A direction exhibiting the highest tensile strength was defined as the longitudinal direction, and a direction perpendicular to the longitudinal direction was defined as the lateral direction, where a longitudinal/lateral strength ratio was then calculated from the measured values. The results are shown in Tables 1 to 3.

TABLE 1

| | | Working | | Working | | Working | | Working | |
|---|---|---|---|---|---|---|---|---|---|
| | | example 1 | | example 2 | | example 3 | | example 4 | |
| Specific resistance | | 1.82E−04 | | 1.50E−03 | | 2.50E−03 | | 1.82E−04 | |
| Tensile | Direction of | Longitudinal | Lateral | Longitudinal | Lateral | Longitudinal | Lateral | Longitudinal | Lateral |
| strength | unwoven cloth | direction | direction | direction | direction | direction | direction | direction | direction |
| | Strength (MPa) | 16 | 15 | 14 | 13 | 17 | 15 | 19 | 18 |

| | | | | |
|---|---|---|---|---|
| Longitudinal/lateral | 1.07 | 1.08 | 1.13 | 1.06 |
| strength ratio | | | | |

| | | | | | | | | |
|---|---|---|---|---|---|---|---|---|
| Transmission loss (dB) with | 90 | 90 | 62 | 60 | 58 | 60 | 92 | 90 |
| longitudinal electromagnetic | | | | | | | | |
| wave (70 GHz) | | | | | | | | |

| | | | | |
|---|---|---|---|---|
| Transmission loss ratio | 1.00 | 1.03 | 0.97 | 1.02 |

TABLE 2

| | | Working | | Working | | Working | | Working | |
|---|---|---|---|---|---|---|---|---|---|
| | | example 5 | | example 6 | | example 7 | | example 8 | |
| Specific resistance | | 1.82E−04 | | 2.50E−04 | | 3.20E−04 | | 1.60E−04 | |
| Tensile | Direction of | Longitudinal | Lateral | Longitudinal | Lateral | Longitudinal | Lateral | Longitudinal | Lateral |
| strength | unwoven cloth | direction | direction | direction | direction | direction | direction | direction | direction |
| | Strength (MPa) | 138 | 130 | 150 | 149 | 103 | 100 | 120 | 115 |

| | | | | |
|---|---|---|---|---|
| Longitudinal/lateral | 1.06 | 1.01 | 1.03 | 1.04 |
| strength ratio | | | | |

| | | | | | | | | |
|---|---|---|---|---|---|---|---|---|
| Transmission loss (dB) with | 90 | 90 | 64 | 62 | 90 | 88 | 86 | 84 |
| longitudinal electromagnetic | | | | | | | | |
| wave (70 GHz) | | | | | | | | |

| | | | | |
|---|---|---|---|---|
| Transmission loss ratio | 1.00 | 1.03 | 1.02 | 1.02 |

TABLE 3

| | | Comparative | | Comparative | | Comparative | |
|---|---|---|---|---|---|---|---|
| | | example 1 | | example 2 | | example 3 | |
| Specific resistance | | 1.51E−03 | | 2.22E−03 | | 1.39E−03 | |
| Tensile | Direction of | Longitudinal | Lateral | Longitudinal | Lateral | Longitudinal | Lateral |
| strength | unwoven cloth | direction | direction | direction | direction | direction | direction |
| | Strength (MPa) | 82 | 47 | 40 | 22 | 225 | 174 |

| | | | |
|---|---|---|---|
| Longitudinal/lateral | 1.74 | 1.82 | 1.29 |
| strength ratio | | | |

| | | | | | | |
|---|---|---|---|---|---|---|
| Transmission loss (dB) with | 70 | 64 | 60 | 54 | 50 | 45 |
| longitudinal electromagnetic | | | | | | |
| wave (70 GHz) | | | | | | |

| | | | |
|---|---|---|---|
| Transmission loss ratio | 1.09 | 1.11 | 1.11 |

As can be seen from the working examples I to 8 and comparative examples I to 3. by employing a carbon nanotube unwoven cloth exhibiting no difference in tensile strength in the longitudinal and lateral directions. there was obtained a highly reliable electromagnetic wave shielding sheet having an electromagnetic wave shielding property that is unaffected by the oscillation directions of electromagnetic waves.

What is claimed is:

1. An electromagnetic wave shielding sheet comprising a carbon nanotube unwoven cloth that has a thickness of not larger than 1 mm, a specific resistance of not larger than 0.005 Ω·cm, and a longitudinal/lateral tensile strength ratio of 0.8 to 1.25.

2. An electromagnetic wave shielding sheet with a carbon nanotube unwoven cloth that has a thickness of not larger than 1 mm, a specific resistance of not larger than 0.005 Ω·cm, and a longitudinal/lateral tensile strength ratio of 0.8 to 1.25 being impregnated with a resin; and/or with the resin being laminated on the carbon nanotube unwoven cloth.

3. The electromagnetic wave shielding sheet according to claim 2, wherein the resin with which the carbon nanotube unwoven cloth is impregnated and/or that is laminated on the carbon nanotube unwoven cloth is uncured.

4. The electromagnetic wave shielding sheet according to claim 2, wherein the resin with which the carbon nanotube unwoven cloth is impregnated and/or that is laminated on the carbon nanotube unwoven cloth is cured.

5. The electromagnetic wave shielding sheet according to claim 2, wherein the resin with which the carbon nanotube unwoven cloth is impregnated and/or that is laminated on the carbon nanotube unwoven cloth is a heat-curable resin.

6. The electromagnetic wave shielding sheet according to claim 2, wherein the resin with which the carbon nanotube unwoven cloth is impregnated and/or that is laminated on the carbon nanotube unwoven cloth is a thermoplastic resin.

7. The electromagnetic wave shielding sheet according to claim 2, wherein the resin with which the carbon nanotube unwoven cloth is impregnated and/or that is laminated on the carbon nanotube unwoven cloth is in an amount of 10 to 1,000 parts by mass per 100 parts by mass of the carbon nanotube unwoven cloth.

8. The electromagnetic wave shielding sheet according to claim 2, wherein the carbon nanotube unwoven cloth is a carbon nanotube unwoven cloth that has been treated with a coupling agent.

9. The electromagnetic wave shielding sheet according to claim 5, wherein the heat-curable resin is at least one kind selected from the group consisting of an epoxy resin, an allylated epoxy resin, an allylated polyphenylene ether resin, a maleimide resin, a bismaleimide resin, a cyanate resin, a cyclopentadiene-styrene copolymer resin, a silicone resin, a phenolic resin, and an acrylic resin.

10. The electromagnetic wave shielding sheet according to claim 6, wherein the thermoplastic resin is at least one kind selected from the group consisting of polyethylene, polypropylene, polyphenylene ether, polyetheretherketone, polyetherketone, polyethersulfone, and fluorine resin.
